(19) United States
(12) Patent Application Publication
(10) Pub. No.: US 2025/0260416 A1
(43) Pub. Date: Aug. 14, 2025

(54) COMPARATOR CAPABLE OF OPERATING AT LOW POWER SUPPLY VOLTAGE

(71) Applicant: Cisco Technology, Inc., San Jose, CA (US)

(72) Inventor: Oleksiy ZABRODA, Constable, NY (US)

(21) Appl. No.: 18/438,116

(22) Filed: Feb. 9, 2024

(51) Int. Cl. H03M 1/36; H03M 1/00; H03M 1/12

(52) U.S. Cl. CPC H03M 1/361; H03M 1/002; H03M 1/1255

(57) ABSTRACT

Embodiments herein describe a comparator with a preamplifier that includes output transistors that help drive output nodes of a latch. In one embodiment, when the latch is in an active mode, the output transistors in the preamplifier help latch transistors in the latch to drive the output nodes of the latch to a valid (e.g., correct) output. In one embodiment, the output transistors and the latch transistors form parallel current paths to the output nodes, which substantially increase the latch speed.

### TECHNICAL FIELD

Embodiments presented in this disclosure generally relate to electric signal comparators, especially those suitable for operation at low power supply voltages. Such comparators are beneficial for applications in wide variety of mixed signal electronic devices, including high speed time interleaved analog to digital converters.

### BACKGROUND

Most modern high-speed communications devices are based on a digital signal processing (DSP) architecture. One of the key components of the receivers in such devices is a high-speed analog to digital converter (ADC) operating at conversion rates between 50-200 Gs/s. Such conversion rate can be achieved only if a time interleaved architecture is used for the ADC. Successive approximation analog to digital converters (SAR ADC) are typically the most common building blocks for high-speed time interleaved ADCs primarily due to the best achievable figure of merit compared to the other current architectures. There are obvious reasons for a strong demand in power supply voltage reduction in all types of very large-scale integration (VLSI) solid state circuits. The same is relevant to the mixed signal integrated circuits (ICs), essential parts of which are the ADCs.

One of the main components that limit the power supply voltage reduction of such circuits is the latch-based comparator. The operation speed of the comparator is dramatically reduced if the power supply voltage is low. Thus, in order to operate a comparator, especially at low power supply voltages, the speed of operation should be preserved. One of the main factors limiting the comparators is multiple transistors coupled in series between voltage rails (e.g., VDD and VSS), which limits the amount of current that can flow through the comparator. While the size of the transistors in the comparator can be increased, the parasitic capacitance of the transistors increases proportionally with the size of the transistors, which means increasing their size only leads to excessive power consumption with little to no impact on the speed of the comparator.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an ADC, according to one embodiment.

FIG. 2 illustrates a comparator, according to one embodiment.

FIG. 3 illustrates a comparator, according to one embodiment.

FIG. 4 illustrates timing charts showing the operation of the comparator in FIG. 3, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a comparator latch for an analog to digital converter (ADC). The comparator latch includes a preamplifier stage configured to receive and amplify analog input signals and a latch stage configured to store an output of the comparator latch. Moreover, a first transistor in the latch stage and a second transistor in the preamplifier stage work together to drive an output node of the latch stage when the latch stage is in an active mode, and the second transistor drives the output node in both the active mode and a reset mode of the latch stage.

Another embodiment presented in this disclosure is a method that includes driving output nodes of a latch in a comparator to a rail voltage during a reset mode; providing, during the reset mode, an amplified signal to the output nodes using output transistors in a preamplifier in the comparator; generating, during an active mode of the latch, a valid output at the output nodes using latch transistors in the latch, and driving the output nodes to the valid output using the output transistors during the active mode.

Another embodiment presented in this disclosure is a comparator that includes an amplifier configured to convert input voltages into currents and a latch configured to store an output of the comparator based on the currents. Moreover, a first transistor in the latch and a second transistor in the amplifier work together to drive an output node of the latch when the latch is in an active mode, and the second transistor drives the output node in both the active mode and a reset mode of the latch.

### EXAMPLE EMBODIMENTS

Embodiments herein describe a comparator which includes a latch and a preamplifier that drives the output nodes of the latch. In one embodiment, when the latch is in an active mode, the current provided by the preamplifier flows in the same direction as the latch current helping the transistors in the latch to drive the output nodes of the latch to a valid (e.g., correct) output. In one embodiment, the preamplifier transistors and the latch transistors form parallel current paths to the output nodes, which substantially increase the latch speed (and the overall speed of an ADC containing the comparator).

In one embodiment, the transistors in the preamplifier driving the latch remain in a saturation region for much of the time, and can help the latch enter into a regenerative mode without substantial help of the latch transistors. This ensures the latch functions properly even in a subthreshold voltage range. Thus, the comparators described herein are suitable for operation at low power supply voltages.

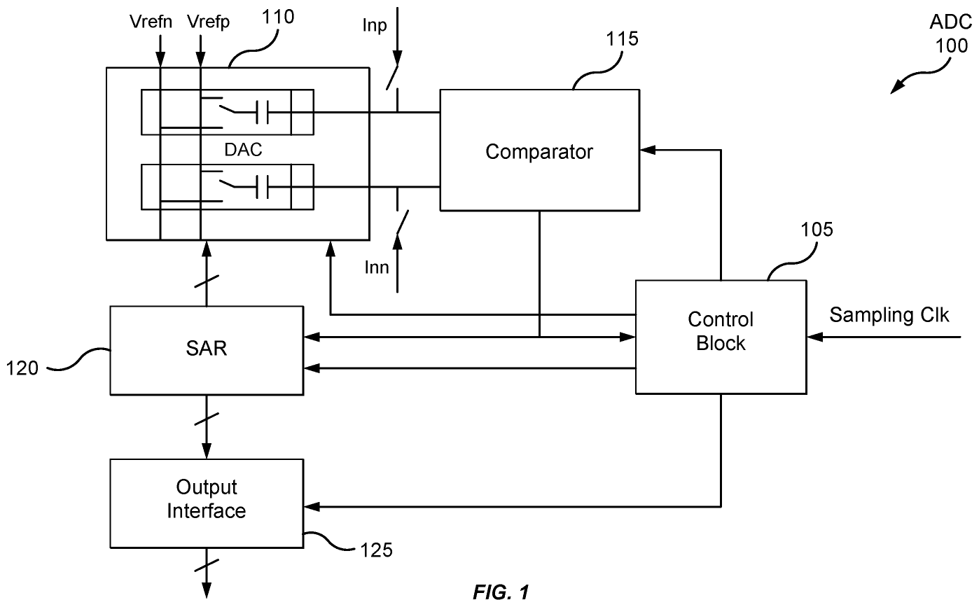

FIG. 1 illustrates an ADC 100, according to one embodiment. In one embodiment, the ADC 100 is a SAR ADC that executes a consecutive bit-by-bit search algorithm starting from the most significant bit to convert an analog input into a multi-bit digital signal.

The ADC 100 includes a control block 105, a differential switched capacitor digital to analog converter (DAC) 110 composed of binary weighted capacitors (only one pair is shown just for illustration), a comparator 115, a successive approximation register (SAR) 120, and output digital data register/buffers 125.

The control block 105 receives an input clock used to sample the input signal (positive input (Inp) and negative input (Inn)) and to initialize the conversion algorithm. Other signals, which control the conversion procedure including the comparator clock, are derived from outputs of the comparator. In one embodiment, the search algorithm starts with the most significant bit (MSB) and bit-by-bit moves down to the least significant bit (LSB). To do so, the output voltage of the DAC 110 is applied to the comparator 115, which determines whether the input is above or below zero (i.e., is negative or positive). If negative, the MSB is assigned a value of 1, but if negative the MSB is assigned a value of 0.

The output voltage of the DAC is then updated based on the output of the comparator and the ADC 100 can then move to next most significant bit and the process can repeat until all the bits in the digital output (e.g., B[(n−1):0] where n is the total number of bits in the digital output) have been assigned.

The SAR 120 is used to hold the values of the converted bits and to control the capacitors switches of the switched capacitor DAC 110. At the end of the conversion, the SAR 120 sends the converted data to the output digital data register/buffers 125.

As mentioned above, one of the main components limiting the power supply voltage reduction of such circuits is the latch-based comparators 115. The latch-based comparators 115 can include multiple transistors connected in series that share the available power supply voltage. Their combined impedance limits the speed of the latch, especially at reduced voltages. That is, due to transistors being coupled in series, the voltage across each of the transistors is reduced in proportion to the number of transistors in series.

While reducing the number of transistors in series can improve latch speeds, if the power supply voltage is close to the sum of the threshold voltages of PMOS and NMOS transistors (which is a situation that is quite common in digital circuits), the available current, which is limited by the series connected transistors, creates significant time delays, especially in the conditions close to metastability. Additionally, in many known applications, where a dynamic preamplifier topology is used, the transistors in the preamplifier can fight with the currents generated by transistors in the latch that drive the output of the latch, further increasing the delay.

Instead, as described in more detail in the figures that follow, the comparator 115 can include one or more transistors in an amplifier (e.g., a preamplifier) that create a parallel current path and assist the transistors in the latch to drive the output of the comparator to the valid common mode and differential voltage output. Further, instead of the transistors in the amplifier fighting the transistors in the latch, the amplifier transistors help drive the output of the comparator during at least a portion of the time that the latch is in an active mode.

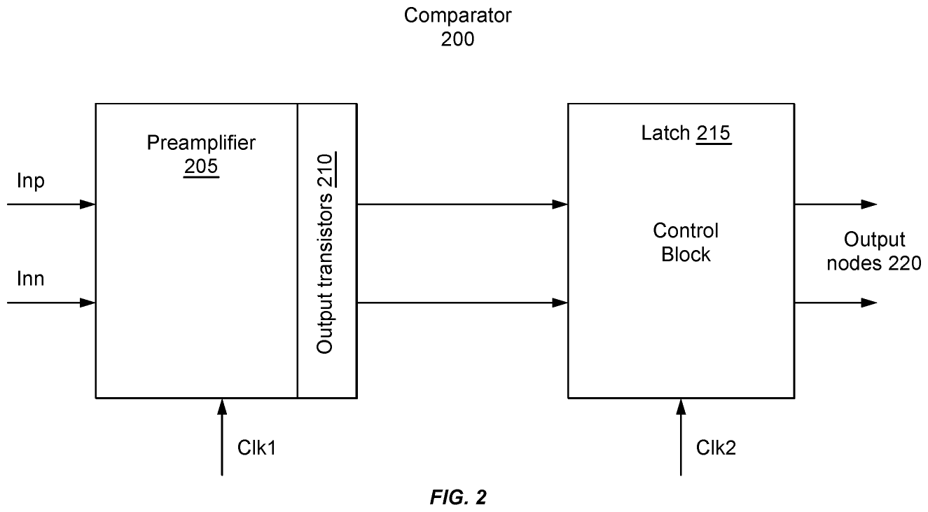

FIG. 2 illustrates a comparator 200, according to one embodiment. In one embodiment, the comparator 200 is one example implementation of the comparator 115 in FIG. 1.

As shown, the comparator 200 includes a switched preamplifier 205 (e.g., a preamplifier stage) and a latch 215 (e.g., a latch stage). Both the preamplifier 205 and the latch 215 can include circuitry (e.g., hardware) that perform the functions described herein. In one embodiment, the preamplifier 205 receives voltage inputs, e.g., the voltages Inp and Inn in FIG. 1. The preamplifier 205 can convert the input voltages to currents which are then provided to the latch 215. In one example, the preamplifier 205 converts the voltage difference at the input nodes to the current difference at the output nodes of the comparator 200. For instance, the preamplifier 205 may convert the voltage difference at the input into the current difference at the output, thus acting as a switched transconductance amplifier or gm-cell.

The switched preamplifier 205 is controlled by clock signal Clk1 while the latch 215 is controlled by clock signal Clk2. During the active phases of the respective clock signals, the preamplifier 205 and the latch 215 are enabled to process their input signals. During the opposite phases of the clock signals, the preamplifier 205 and the latch 215 are in a reset mode of operation. The active phases of both clocks can overlap in such a way that the preamplifier 205 remains enabled during some time interval after enabling the latch 215. As it will be explained later, Clk1 can be just a delayed version of clock signal Clk2 or vice-versa.

The latch 215 compares the current difference and converts it into a digital output signal. However, there are cases when just amplifiers with very high voltage gain can execute the comparator function, as well as there are comparators, which contain only a latch (i.e., no amplification circuitry).

In this example, the preamplifier 205 includes output transistors 210 that are used in both the reset mode and the regeneration mode (at least partially) to drive the output nodes 220 of the latch 215. In one embodiment, the output transistors 210 are directly connected to the output node 220. That is, there may not be any transistors between the transistors 210 in the preamplifier 205 and the output nodes 220 in the latch 215.

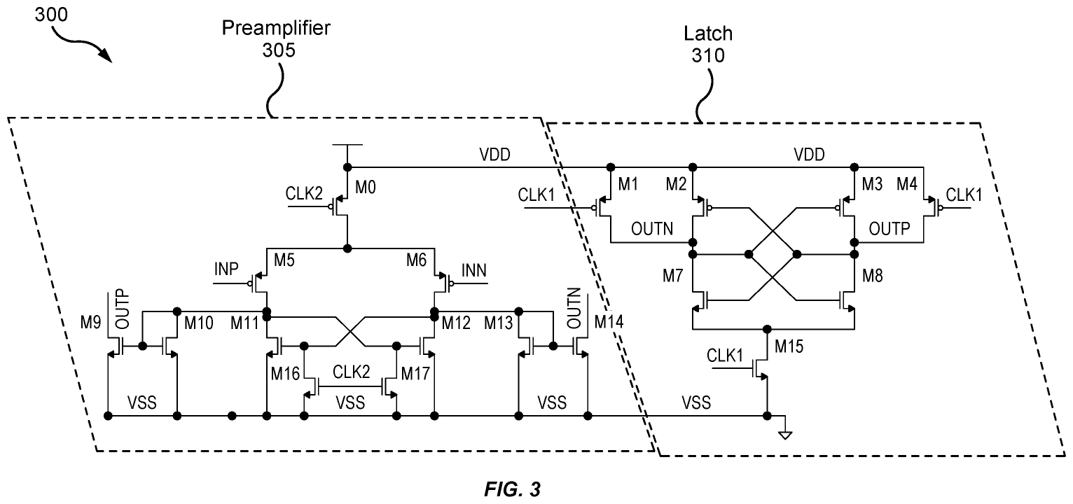

Although not shown, the latch 215 includes its own transistors for driving the output node 220 (referred to as latch transistors). In one example, the latch transistors are also directly coupled to the output node 220. For instance, the preamplifier output transistors 210 can provide a first set of current paths for driving the output node 220 while the latch transistors provide a second, parallel set of current paths for driving the output node 220. One circuit implementation of a comparator containing a preamplifier and a latch is shown in FIG. 3.

FIG. 3 illustrates a comparator 300, according to one embodiment. The comparator 300 is one circuit implementation of the comparator 200 which includes the preamplifier output stage transistors 210, which are transistors M9 and M14 in FIG. 3.

As shown, the comparator 300 includes preamplifier circuitry 305 and latch circuitry 310. The inputs (or input nodes) to the comparator 300 are labeled INP and INN. The outputs (or output nodes) of the comparator 300 are labeled OUTP and OUTN. Various PMOS and NMOS transistors are labeled M0-M17 in the figure. Further, the comparator includes a clock signal (CLK1) controlling the preamplifier circuitry and a clock signal (CLK2) controlling the latch circuitry The comparator also includes two DC voltage sources, or voltage rails (VDD and VSS).

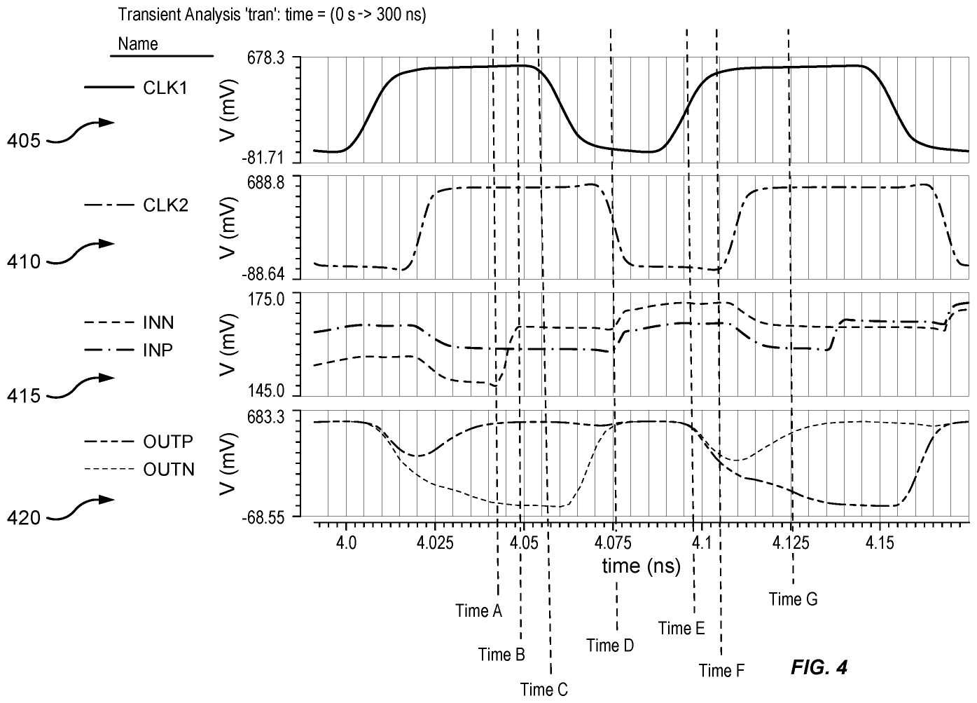

While the details of the operation of the comparator 300 will be discussed using the timing diagrams in FIG. 4, as a brief overview, the preamplifier circuitry 305 includes two output transistors M9 and M14 where both their drains are directly connected to OUTP and OUTN. That is, the NMOS transistors M9 and M14 are directly connected to the output nodes of the latch circuitry 310. M9 and M14 are used during at least a portion of the active mode of the latch to drive a valid output onto OUTP and OUTN.

The latch circuitry 310 includes transistors M7 and M8 (i.e., NMOS transistors) which also drive OUTP and OUTN during the active mode of the latch. That is, the transistors M9 and M8 form parallel current paths to drive OUTP while the transistors M14 and M7 form parallel current paths to drive OUTN during at least a portion of the active mode of the latch.

One important feature of prior art comparators is activating the preamplifier components and latch components (e.g., transistors) using the same clock edge. Often, the amplifier/preamplifier portion of the comparator is controlled by the active high clock, while the latch portion is controlled by active low complementary clock, thus basically by the same clock edge. However, in the majority of SAR ADC implementations, the signal at the comparator input is settled and available for evaluation substantially before the end of the reset mode of the comparator latch. Thus, using both clock edges might speed-up the comparator performance.

The comparator 300 is one example circuitry that uses this feature. The preamplifier circuitry 305 is controlled by clock CLK1 (active low), which is a delayed version of clock CLK2, and the latch circuitry 310 is controlled by clock CLK2 (active high). Thus, the preamplifier circuitry 305 is activated by the falling edge of the CLK1 (while the latch is in the reset mode) and the latch circuitry 310 is activated by the rising edge of the CLK2.

The preamplifier circuitry 305 contains a differential pair of PMOS transistors M5 and M6 operating with the active load transistors M10, M11, M12 and M13. The combination of cross-coupled and diode connected load transistors provides several useful features: the load has “virtually indefinite” differential resistance and acts like a diode for common mode current.

The preamplifier circuitry 305 is coupled with the latch circuitry 310 through two current mirrors based on transistors M9, M10 and M13, M14. When clock CLK1 is high, the preamplifier circuitry 305 is in the reset mode or reset phase of operation. Under these conditions, the switch transistor M0 is off and the nodes of the active load transistors are discharged through transistors M16 and M17. When CLK1 is low, the preamplifier circuitry 305 is in an active mode of operation. Transistor M0 switches to an on state, coupling the source nodes of the transistors of the differential pair to VDD. Under these conditions the current of transistors M5 and M6 is controlled by the proper choice of the common mode voltage value of the input signals INP and INN. Through the current mirror output transistors M9 and M14, the amplified output current is sent to the output nodes of the latch (OUTP and OUTN). One important feature of the preamplifier circuitry 305 is that the operating power supply range is extending below the sum of threshold voltages of CMOS transistors. This is because the differential pair transistors M5 and M6 can successfully operate with the source-drain voltages being lower than the source-gate voltage and still be in a saturation.

The latch circuitry 310 has a minimal configuration. It contains cross-coupled transistors M2, M3, M7 and M8, switch transistor M15 and reset transistors M1 and M4. When clock CLK2 is low, the latch is in a reset mode/phase. The switch transistor M15 is off, and the output nodes OUTN and OUTP are pulled up to VDD by the reset transistors M1 and M4. The operation of the latch circuitry 310 when in the active mode (the regeneration phase) will be described using the timing diagrams of FIG. 4.

FIG. 4 illustrates timing diagrams showing the operation of the comparator in FIG. 3, according to one embodiment. The signals of the timing diagrams are derived from the operation of a SAR ADC depicted in FIG. 1. The timing diagrams are grouped in four charts: Chart 405 illustrates the CLK2 signal shown in FIG. 3. Chart 410 illustrates the CLK1 signal shown in FIG. 3. Chart 415 illustrates the inputs INN and INP shown in FIG. 3. Chart 420 illustrates the outputs OUTP and OUTN shown in FIG. 3.

At Time A (approximately 4.04 ns) the comparator has evaluated the previous value of the input voltages INN and INP provided by the SAR ADC switch capacitor DAC (e.g., the DAC 110 in FIG. 1), where the result of this evaluation is used by to produce a new input voltage value which is shown in chart 415. The new input value has settled at Time B (approximately 4.05 ns).

At Time C (approximately 4.055 ns), chart 405 illustrates the clock signal CLK2 going down which causes the latch to enter the reset mode. As a result, chart 420 illustrates that the outputs of the latch are pulled to VDD by Time D (approximately 4.075 ns). Also at Time D, the chart 410 illustrates the preamplifier clock signal CLK1 going down, enabling the preamplifier stage of the comparator. At this moment the kick-back effect pulls both inputs INP and INN up by approximately 5 mV as shown by chart 415.

At this time, the current produced by output transistors M9 and M14 of the preamplifier in FIG. 3 is not able to significantly change the voltage of latch output nodes OUTN and OUTP since they are clamped to the VDD by the reset transistors M1 and M4. This is illustrated in chart 420 where OUTN and OUTP remain at VDD from Time D to Time E, despite being driven by the preamplifier output transistors.

At Time E (approximately 4.95 ns), the chart 405 illustrates the clock signal CLK2 going high which switches the latch to the active mode. In this mode, the reset transistors M1 and M4 are disabled and chart 420 illustrates voltages of the latch output nodes OUTP and OUTN, which are driven by the preamplifier output transistors M9 and M14 as well as the latch transistors M7 and M8, rapidly going down. The latch enters a regenerative phase and produces valid outputs by Time G (approximately 4.125 ns). Until Time F (approximately 4.105 ns), the preamplifier stage was actively providing additional currents to the latch output nodes using the preamplifier output transistors M9 and M14.

In one embodiment, the preamplifier output transistors (e.g., the transistors M9 and M14 in FIG. 3) may not drive the output nodes for the entire time the latch is in the active mode or the regenerative phase. For example, the preamplifier output transistors may drive the output nodes in parallel with the latch transistors from Time E to Time F in FIG. 4. That is, Time E to Time F is an overlapping time period where both the amplifier output transistors and the latch transistors work together to drive the output nodes. When the overlapping time period expires, only the latch transistors drive the output nodes. For example, at Time F, the preamplifier may be disabled which stops the output transistors of the preamplifier from driving the output nodes, and only the latch transistors drive the output nodes until the latch again switches into the reset mode (e.g., when the CLK2 signal goes low).

Using the preamplifier output transistors simultaneously driving the output nodes in parallel with the latch transistors at the beginning of the latch active mode of operation is one feature that is different from other current comparators. Usually, the output nodes of the latch are precharged to some voltage difference before the latch enters the regenerative phase because of the concern that the latch would react on the noise signal at the output nodes rather than the input signal, and the comparator would have high value of the input referred noise.

The embodiments herein use the fact that the internal noise of the comparator can be noticeable only when the differential input signal of the comparator is low. In this situation the latch remains in a metastability condition for an extended time interval, which is sufficient for the preamplifier to produce the full-strength voltage difference at the latch output. Also, because the preamplifier and the latch are controlled by different clock signals, the preamplifier is able to produce much stronger output signal compared to the traditional prior art dynamic preamplifiers, which is able to completely override the noise generated by the latch. In the embodiment depicted in FIG. 3, only the preamplifier components contribute to the total input referred noise figure while the noise contribution of the latch is not noticeable.

From charts 405 and 410 it is apparent that CLK1 is a delayed version of CLK2 and the duration of the active phase of CLK1 is equal to the duration of the reset phase of CLK2, which is substantially shorter than the active phase of CLK2 during the conversion phase of the SAR ADC. Thus, it may be beneficial to keep CLK2 and CLK1 high during the tracking and sampling phase of the SAR ADC. In this case, the preamplifier will be idle and will not consume any current. Also, this time can be added to the conversion of the least significant bit.

This advantageous feature of the comparator provides the following benefits. One, as soon as clock CLK2 goes high as shown in chart 405, the latch output nodes are charged by two parallel current paths (M9/M8 and M14/M7) which substantially increase the latch speed. In comparison, in previous latch designs, the charging paths of the output nodes contain three (or more) series connected transistors, or the amplifier transistors fight with the latch transistors.

Two, since transistors M9 and M14 of the preamplifier of FIG. 3 operate in a saturation region for most of the time, together with the latch transistors M2 and M3, they can enter in a regenerative phase even without substantial help from transistors M7 and M8. This ensures the functionality of the latch even in subthreshold voltage range.

At Time F, chart 410 illustrates the clock signal CLK1 going up disabling the preamplifier stage and causing a kick-back effect at the input nodes INN and INP in chart 415. Notably, the common mode variation of the comparator inputs does not cause the deterioration of the comparator accuracy. This a common feature of many dynamic amplifiers and latches. Also, in this embodiment, the preamplifier stage is active for the time needed for the comparator latch to reset. In the case presented in FIG. 4, it is only 30 ps. Thus, the current consumption of the preamplifier depicted in FIG. 3 should be comparable with a traditional dynamic preamplifier used in a prior art comparators.

The comparator topology in FIGS. 2 and 3 and its operation shown in FIG. 4 demonstrate an improved speed of operation, especially at low power supply voltage values.

In one embodiment, during a reset mode (e.g., when the CLK2 signal in chart 405 in FIG. 4 goes low), the output nodes of the latch are driven to a rail voltage (e.g., VDD). Because the clock CLK1 is delayed relative to CLK2, CLK1 does not switch from low to high (e.g., as shown by Time D in FIG. 4) until sometime after the CLK2 signal switched from low to high. When CLK1 goes low, this enables the preamplifier in the comparator.

After this, the amplifier provides an amplified signal to the output nodes of the latch (e.g., OUTP and OUTN) using output transistors (e.g., M9 and M14 in FIG. 3). This can correspond to Time D in FIG. 4 where the preamplifier is enabled but the latch remains in the reset mode.

At this time, in one embodiment, the current produced by the output transistors in the preamplifier is not able to significantly change the voltage of latch output nodes OUTN and OUTP since these nodes are clamped to the VDD by the reset transistors in the latch (e.g., M1 and M4 in FIG. 3). Thus, in this embodiment, the output transistors actively drive the output nodes while the latch is still in the reset mode, but do not have a substantial effect on the voltages of the output nodes.

In one embodiment, latch transistors in the latch (e.g., M7 and M8 in FIG. 3) generate a valid output in an active mode. The latch switches into the active mode when the CLK2 signal goes high as shown at Time E in FIG. 4. The latch transistors can continue to drive the output of the latch in the active mode until the CLK2 signal goes low again and the latch enters the reset mode.

At the same time (e.g., in parallel) when the latch switches into the active mode when the CLK2 signal goes high as shown at Time E in FIG. 4, the output transistors in the preamplifier can drive the output nodes to the valid output. That is, transistors in the preamplifier assist the transistors in the latch (e.g., the output transistors and the latch transistors work together) to drive a valid output onto the output nodes. Because the output transistors were already driving the output nodes while the latch was still in the reset mode, when the latch switches into the active mode (and the output nodes are no longer clamped to VDD), the output transistors can immediately begin affecting the voltage of the output nodes.

In one embodiment, the output transistors may not drive the output nodes for the entire time the latch is in the active mode or the regenerative phase. For example, the output transistors may drive the output nodes in parallel with the latch transistors from Time E to Time F in FIG. 4. That is, Time E to Time F is an overlapping time period where both the output transistors and the latch transistors work together to drive the output nodes. When the overlapping time period expires, only the latch transistors drive the output nodes. For example, at Time F, the preamplifier may be disabled, and only the latch transistors drive the output nodes until the latch again switches into the reset mode.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

As will be appreciated by one skilled in the art, the embodiments disclosed herein may be embodied as a system, method or an entirely hardware embodiment, or an embodiment combining software and hardware aspects that may all generally be referred to herein as a “circuit,” “module” or “system.”

The block diagrams and the timing diagrams in the Figures illustrate the architecture, functionality, and operation of possible implementations of systems, methods according to various embodiments. It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or timing diagram, and combinations of blocks in the block diagrams and/or timing diagrams, can be implemented by special purpose hardware-based systems that perform the specified functions or acts, or combinations of special purpose hardware and computer instructions.

In view of the foregoing, the scope of the present disclosure is determined by the claims that follow.

We claim:

1. A comparator latch for an analog to digital converter (ADC), comprising:
a preamplifier stage configured to receive and amplify analog input signals; and
a latch stage configured to store an output of the comparator latch,
wherein a first transistor in the latch stage and a second transistor in the preamplifier stage work together to drive an output node of the latch stage when the latch stage is in an active mode, wherein the second transistor drives the output node in both the active mode and a reset mode of the latch stage.

2. The comparator latch of claim 1, wherein, when the latch stage enters the active mode, the output node of the latch stage is charged by two parallel current paths formed by the first transistor in the latch stage and the second transistor in the preamplifier stage.

3. The comparator latch of claim 1, wherein a third transistor in the latch stage and a fourth transistor in the preamplifier stage work together to drive a second output node of the latch stage when the latch stage is in the active mode.

4. The comparator latch of claim 3, wherein, when the latch stage enters the active mode, the second output node of the latch stage is charged by two parallel current paths formed by the third transistor in the latch stage and the fourth transistor in the preamplifier stage.

5. The comparator latch of claim 4, wherein the first transistor in the preamplifier stage is directly connected to the output node in the latch stage and the third transistor in the preamplifier stage is directly connected to the second output node in the latch stage.

6. The comparator latch of claim 1, wherein a first clock signal that enables and disables the preamplifier stage is delayed relative to a second clock signal that switches modes of the latch stage.

7. The comparator latch of claim 6, wherein the delay between the first and second clock signals results in an overlapping time period where the preamplifier stage is enabled and the latch stage is active, wherein the first transistor in the latch stage and the second transistor in the preamplifier stage are configured to work together to drive the output node of the latch stage during the overlapping time period.

8. The comparator latch of claim 7, wherein, after the overlapping time period expires, the second transistor in the preamplifier stage is configured to stop driving the output node but the first transistor in the latch stage continues to drive the output node until the latch stage is switched into the reset mode.

9. A method, comprising:
driving output nodes of a latch in a comparator to a rail voltage during a reset mode;
providing, during the reset mode, an amplified signal to the output nodes using output transistors in a preamplifier in the comparator;
generating, during an active mode of the latch, a valid output at the output nodes using latch transistors in the latch; and
driving the output nodes to the valid output using the output transistors during the active mode.

10. The method of claim 9, wherein generating the valid output using the latch transistors and driving the output nodes using the output transistors is performed at least partially during an overlapping time period.

11. The method of claim 9, wherein, for a time period when the latch is in the active mode, each of the output nodes of the latch are charged by two parallel current paths formed by one of the output transistors in the preamplifier and one of the latch transistors in the latch.

12. The method of claim 9, wherein each of the output transistors in the preamplifier is directly connected to a respective one of the output nodes.

13. The method of claim 9, wherein a first clock signal that enables and disables the preamplifier is delayed relative to a second clock signal that switches modes of the latch.

14. The method of claim 13, wherein the delay between the first and second clock signals results in an overlapping time period where the preamplifier is enabled and the latch is active, wherein the latch transistors in the latch and the output transistors in the preamplifier work together to drive the output nodes of the latch during the overlapping time period.

15. The method of claim 14, wherein, after the overlapping time period expires, the output transistors in the preamplifier stop driving the output nodes but the latch transistor in the latch continues to drive the output nodes until the latch is switched into the reset mode.

16. A comparator, comprising:
an amplifier configured to convert input voltages into currents; and
a latch configured to store an output of the comparator based on the currents,
wherein a first transistor in the latch and a second transistor in the amplifier work together to drive an output node of the latch when the latch is in an active mode, wherein the second transistor drives the output node in both the active mode and a reset mode of the latch.

17. The comparator of claim 16, wherein, when the latch enters the active mode, the output node of the latch is charged by two parallel current paths formed by the first transistor in the latch and the second transistor in the amplifier.

18. The comparator of claim 16, wherein a third transistor in the latch and a fourth transistor in the amplifier work together to drive a second output node of the latch when the latch is in the active mode.

19. The comparator of claim 18, wherein, when the latch enters the active mode, the second output node of the latch is charged by two parallel current paths formed by the third transistor in the latch and the fourth transistor in the amplifier.

20. The comparator of claim 19, wherein the first transistor in the amplifier is directly connected to the output node in the latch and the third transistor in the amplifier is directly connected to the second output node in the latch.
